(19) United States
(12) Patent Application Publication
(10) Pub. No.: US 2015/0228520 A1
(43) Pub. Date: Aug. 13, 2015

(54) Substrate Transfer Robot and Substrate Processing Apparatus Using The Same

(71) Applicant: Eugene Technology Co., Ltd., Yongin-si (KR)

(72) Inventors: Jun-Jin Hyon, Gunpo-si (KR); Byoung-Gyu Song, Yongin-si (KR); Kyong-Hun Kim, Yongin-si (KR); Yong-Ki Kim, Pyeongtaek-si (KR); Yang-Sik Shin, Yongin-si (KR); Chang-Dol Kim, Yongin-si (KR)

(21) Appl. No.: 14/608,422

(22) Filed: Jan. 29, 2015

(30) Foreign Application Priority Data
Feb. 13, 2014 (KR) 10-2014-0016469

(51) Int. Cl. H01L 21/677

(52) U.S. Cl. CPC H01L 21/67778; H01L 21/67739

(57) ABSTRACT

A substrate processing apparatus may include: a loadlock chamber in which a substrate transferred from the outside is disposed, and an internal state thereof is changed to a vacuum state and an atmospheric pressure state; a substrate processing module in which a process is performed on the substrate; a transfer chamber in which the substrate is transferred, the transfer chamber being disposed between the loadlock chamber and the substrate processing module; and a substrate transfer robot installed within the transfer chamber and transferring the substrate.

### CROSS-REFERENCE TO RELATED APPLICATION

This application claims the benefit of Korean Patent Application No. 10-2014-0016469 filed on Feb. 13, 2014, with the Korean Intellectual Property Office, the disclosure of which is incorporated herein by reference.

### BACKGROUND OF THE INVENTION

The present disclosure relates to a substrate processing apparatus and more particularly, to a substrate transfer robot, allowing an increased number of substrates to be disposed within a process chamber while not increasing a size of a transfer chamber, and a substrate processing apparatus using the same.

In general, a transfer robot may be used when two or more wafers are transferred to susceptors so as to be processed within a single chamber in a chemical vapor deposition (CVD) type substrate processing apparatus.

Of interest is Korean Patent Laid-Open Publication No. 2007-0080767 (Aug. 13, 2007)

### SUMMARY OF THE INVENTION

An aspect of the present disclosure may provide a substrate transfer robot allowing an increased number of substrates to be disposed within a process chamber while not increasing a size of a transfer chamber, and a substrate processing apparatus using the same.

An aspect of the present disclosure may also provide a substrate transfer robot and a substrate processing apparatus using the same, capable of processing an increased amount of substrates within the same processing time.

Other aspects of the present disclosure will be further apparent from the following detailed description and the attached drawings.

According to an aspect of the present disclosure, a substrate processing apparatus may include: a loadlock chamber in which a substrate transferred from the outside is disposed, and an internal state thereof is changed to a vacuum state and an atmospheric pressure state; a substrate processing module in which a process is performed on the substrate; a transfer chamber in which the substrate is transferred, the transfer chamber being disposed between the loadlock chamber and the substrate processing module; and a substrate transfer robot installed within the transfer chamber and transferring the substrate.

The substrate transfer robot may include: a base frame part rotatably installed on a lower portion of the transfer chamber; a first rotating frame part having one end rotatably connected to the base frame part; a second rotating frame part having one end rotatably connected to the other end of the first rotating frame part; and a transfer frame part including an arm portion having one end rotatably connected to the other end of the second rotating frame part and a holder portion connected to the other end of the arm portion and allowing the substrate to be disposed on the holder portion.

The transfer chamber may have an internal space having a circular horizontal cross-section.

The first rotating frame part may have a linear form and a length less than a radius of the internal space, and the one end of the first rotating frame part may be positioned in a central portion of the internal space.

The transfer frame part may have a linear form and a length less than a diameter of the internal space.

The substrate transfer robot may include: a central axis coupled to the transfer chamber and the base frame part; a first rotational axis coupled to the base frame part and the one end of the first rotating frame part; a second rotational axis coupled to the other end of the first rotating frame part and the one end of the second rotating frame part; a third rotational axis coupled to the other end of the second rotating frame part and the one end of the arm portion; and a central motor, a first motor, a second motor, and a third motor connected to the central axis, the first rotational axis, the second rotational axis, and the third rotational axis, respectively, to provide the central axis, the first rotational axis, the second rotational axis, and the third rotational axis with rotational driving force.

The substrate processing module may include: a process chamber including a first process space and a second process space divided by a partition and having a first passage and a second passage formed in one side thereof, the first passage and the second passage allowing the substrate to access the first process space and the second process space; a first susceptor installed within the process chamber, disposed in front of each of the first passage and the second passage, having a plurality of through holes formed to penetrate through upper and lower portions thereof, and allowing the substrate to be disposed on the first susceptor during the process; a second susceptor installed within the process chamber, disposed between the first passage and the first susceptor and between the second passage and the first susceptor, having a plurality of through holes formed to penetrate through upper and lower portions thereof, and allowing the substrate to be disposed on the second susceptor during the process; and a plurality of lift pins installed below the first susceptor and the second susceptor and movable through the through holes.

The substrate processing module may include lift pin-driving modules allowing upper ends of the lift pins to be moved to a receiving height higher than the holder portion and a loading height lower than an upper surface of the susceptor.

The substrate transfer robot may include a controlling part connected to the central motor, the first motor, the second motor, and the third motor, and controlling the central motor, the first motor, the second motor, and the third motor in such a manner that the holder portion is moved between a rotating position inside the transfer chamber and a loading position inside the substrate processing module.

The loading position may be one of a first loading position in which the holder portion is disposed above the first susceptor and a second loading position in which the holder portion is disposed above the second susceptor.

In the loading position, the second rotating frame part and the holder portion may be positioned on the same side based on the first rotating frame part.

In the rotating position, the second rotating frame part and the holder portion may be positioned on opposite sides based on the first rotating frame part.

When the holder portion is moved between the rotating position and the loading position, the controlling part may rotate the first motor and the third motor in the same direction while rotating the second motor in a direction different from that of the first motor.

According to another aspect of the present disclosure, a substrate transfer robot may include a rotatable base frame part; at least one rotating frame part rotatably connected to the base frame part in series; a transfer frame part including an arm portion having one end rotatably connected to the rotating frame part and a holder portion connected to the other end of the arm portion and allowing a substrate to be disposed on the holder portion; and a controlling part connected to the base frame part, the rotating frame part, and the transfer frame part and rotating the base frame part, the rotating frame part, and the transfer frame part to limit a moving distance of the holder portion.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic view of a substrate processing apparatus according to an exemplary embodiment of the present disclosure;

FIGS. 2A through 2C are views illustrating operational states of the substrate processing apparatus according to an exemplary embodiment of the present disclosure;

FIGS. 3A through 3C are detailed views illustrating operational states of the substrate processing apparatus according to an exemplary embodiment of the present disclosure;

FIGS. 4A through 4C are views illustrating operational states of a substrate transfer robot according to an exemplary embodiment of the present disclosure;

FIG. 5 is a cross-sectional view of a substrate processing module according to an exemplary embodiment of the present disclosure;

FIGS. 6A through 6F are views illustrating a process of transferring a substrate according to an exemplary embodiment of the present disclosure to a process chamber; and

FIGS. 7A through 7F are views illustrating a process of drawing the substrate according to an exemplary embodiment of the present disclosure from the process chamber.

### DETAILED DESCRIPTION OF THE INVENTION

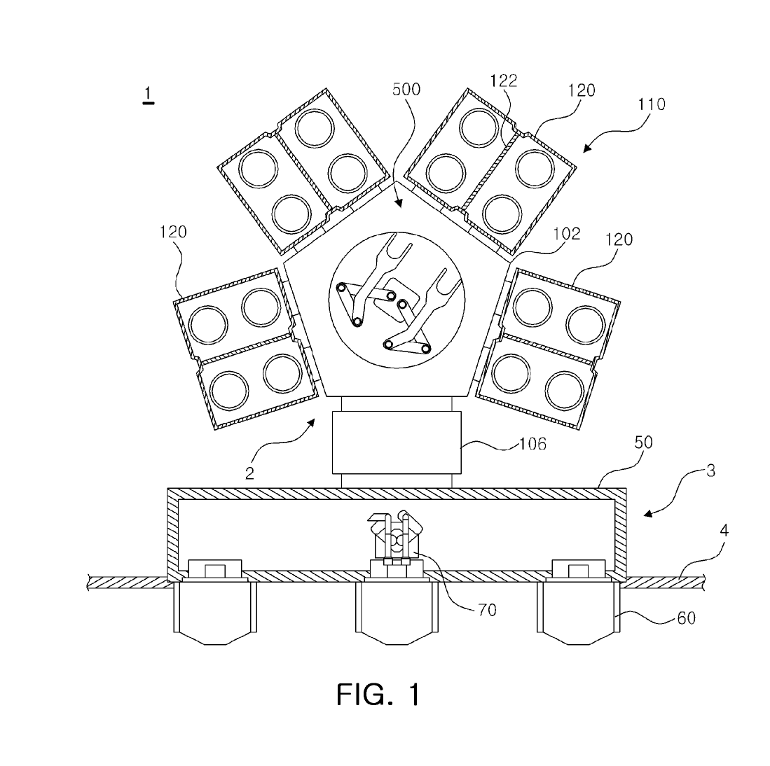

Exemplary embodiments of the present disclosure will now be described in detail with reference to the accompanying FIGS. 1 through 7.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

Meanwhile, hereinafter, a deposition process is exemplified, but the present disclosure may be applied to various processes including the deposition process.

FIG. 1 is a schematic view of a substrate processing apparatus according to an exemplary embodiment of the present disclosure. A substrate processing apparatus 1 according to an exemplary embodiment of the present disclosure may include a piece of process equipment 2, an equipment front-end module (EFEM) 3, and an interface wall 4. The equipment front-end module 3 may be mounted in front of the piece of process equipment 2 and transfer substrates between a container (not shown) receiving the substrates therein and the piece of process equipment 2.

The equipment front-end module 3 may have a plurality of load ports 60 and a frame part 50. The frame part 50 may be positioned between the load ports 60 and the piece of process equipment 2. The container receiving the substrates therein may be disposed on the load ports 60 by a transfer means (not shown) such as an overhead transfer device, an overhead conveyor, or an automatic guided vehicle.

The container may be an airtight container such as a front open unified pod (FOUP). A frame robot 70 maybe installed within the frame part 50, the frame robot 70 transferring the substrates between the container disposed on the load ports 60 and the piece of process equipment 2. A door opener (not shown) automatically opening and closing a door part of the container may be installed within the frame part 50. In addition, a fan filter unit (FFU) (not shown) supplying clean air into the frame part 50 so as to allow the clean air to flow downwardly within the frame part 50, may be installed within the frame part 50.

The substrates may be subjected to a predetermined process within the piece of process equipment 2. The piece of process equipment 2 may include a transfer chamber 102, a loadlock chamber 106, and a substrate processing module 110. The substrates may be transferred within the transfer chamber 102, and the transfer chamber 102 may have a substantially polygonal shape when viewed from above and an internal space having a circular cross-section. The loadlock chamber 106 and the substrate processing module 110 may be installed on side surfaces of the transfer chamber 102.

The loadlock chamber 106 may be positioned on a side portion adjacent to the equipment front-end module 3 among side portions of the transfer chamber 102. After the substrates have temporally remained within the loadlock chamber 106, they may be loaded into the piece of process equipment 2 and may be subjected to a process. After the completion of the process, the substrates may be unloaded from the piece of process equipment 2 and temporally remain within the loadlock chamber 106. The transfer chamber 102 and the substrate processing module 110 may hold vacuum in the interiors thereof, while an internal state of the loadlock chamber 106 may be changed to vacuum and atmospheric pressure. The loadlock chamber 106 may prevent external contaminant materials from being introduced into the transfer chamber 102 and the substrate processing module 110. In addition, during the transfer of the substrates, the substrates may not be exposed outwardly, the growth of an oxide film on the substrates may be prevented.

A gate value (not shown) may be installed between the loadlock chamber 106 and the transfer chamber 102, and between the loadlock chamber 106 and the equipment front-end module 3. When the substrates are transferred between the equipment front-end module 3 and the loadlock chamber 106, the gate value provided between the loadlock chamber 106 and the transfer chamber 102 may be closed. When the substrates are transferred between the loadlock chamber 106 and the transfer chamber 102, the gate valve provided between the loadlock chamber 106 and the equipment front-end module 3 may be closed.

A substrate transfer robot 500 may be installed within the transfer chamber 102. The substrate transfer robot 500 may transfer the substrates between the loadlock chamber 106 and the substrate processing module 110. The transfer chamber 102 maybe sealed in order to maintain vacuum in the interior thereof during the transfer of the substrates. The maintenance of a vacuum state is to prevent the substrates from being exposed to contaminants (for example, O₂, particulate matter and the like).

The substrate processing module 110 maybe provided for deposition of a film on the substrate. FIG. 1 illustrates a case in which the substrate processing module 110 includes four process chambers 120, but the substrate processing module 110 may include five or more process chambers 120. In addition, a module performing another process (for example, a cleaning or etching process) may be installed on a side surface of the transfer chamber 102.

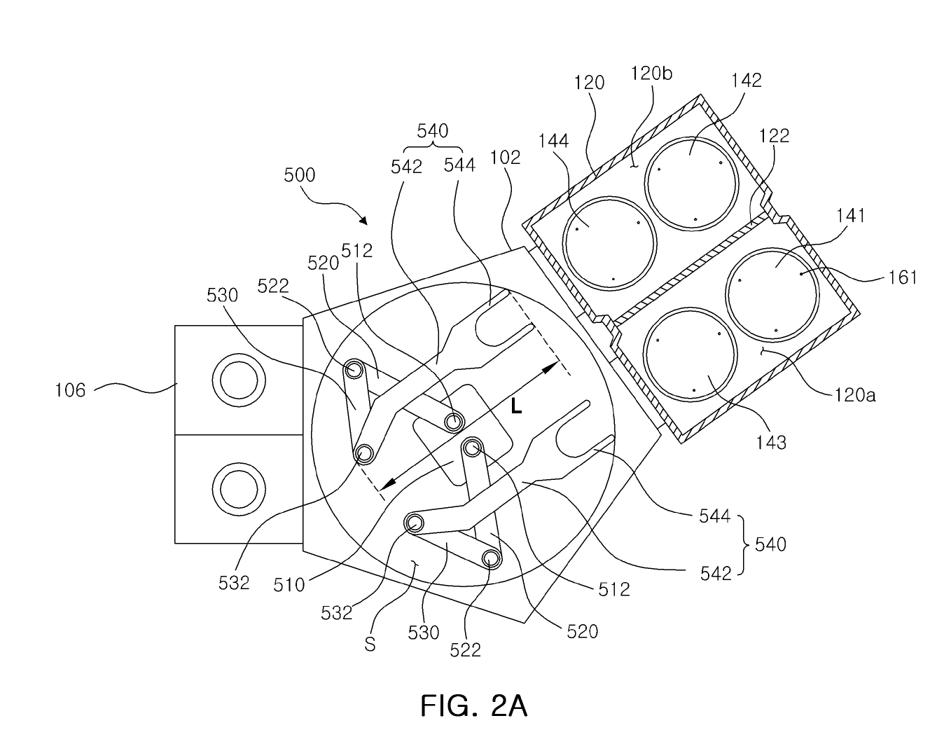

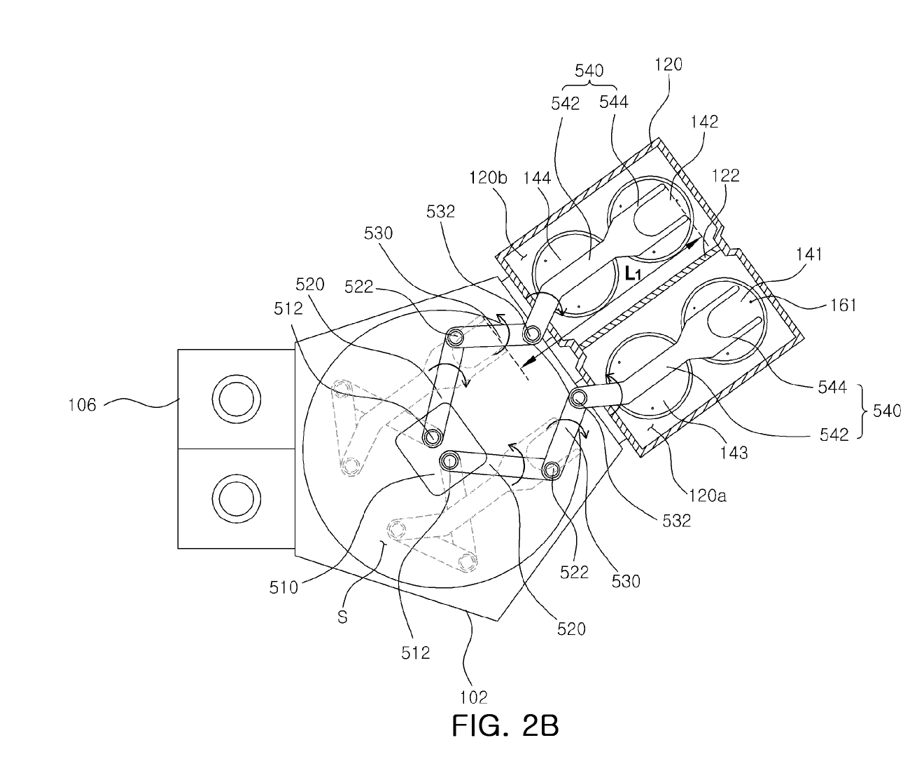

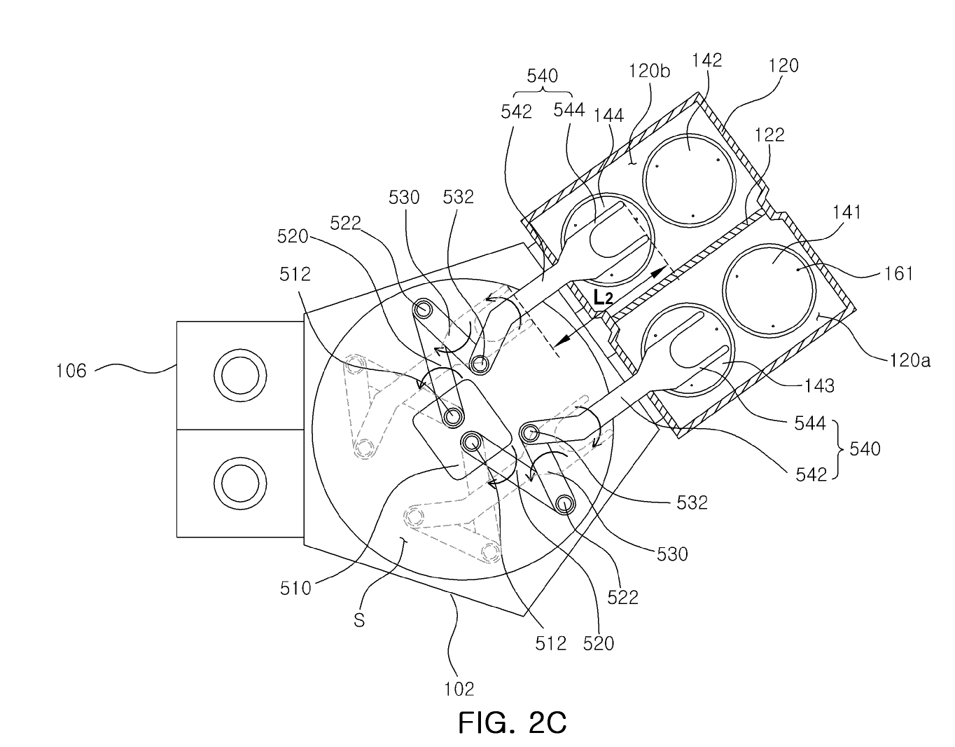

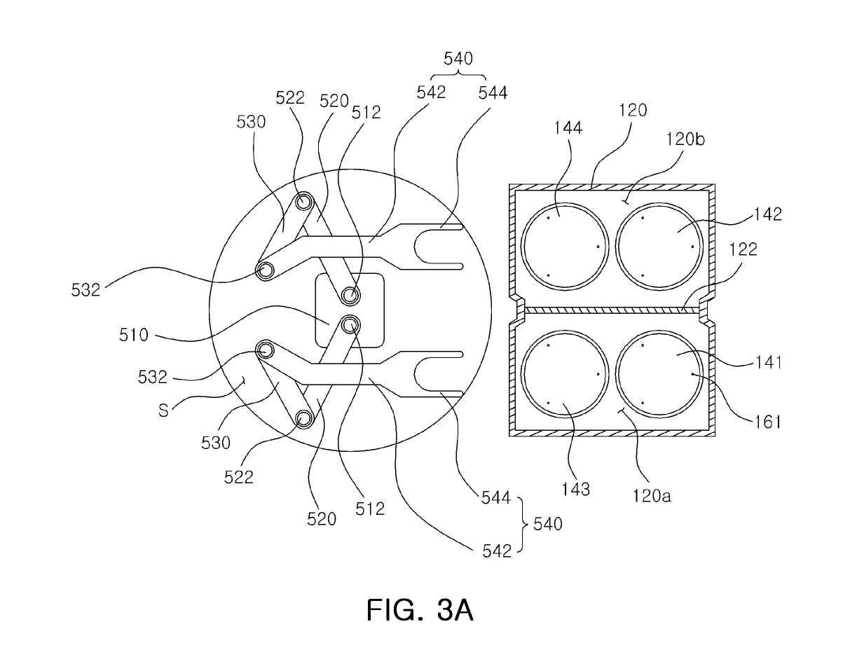

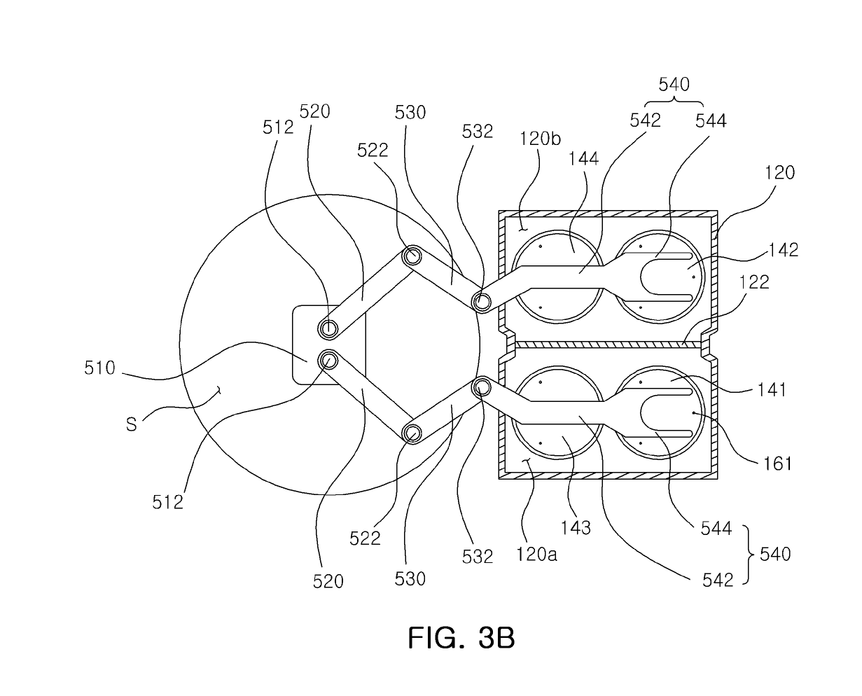

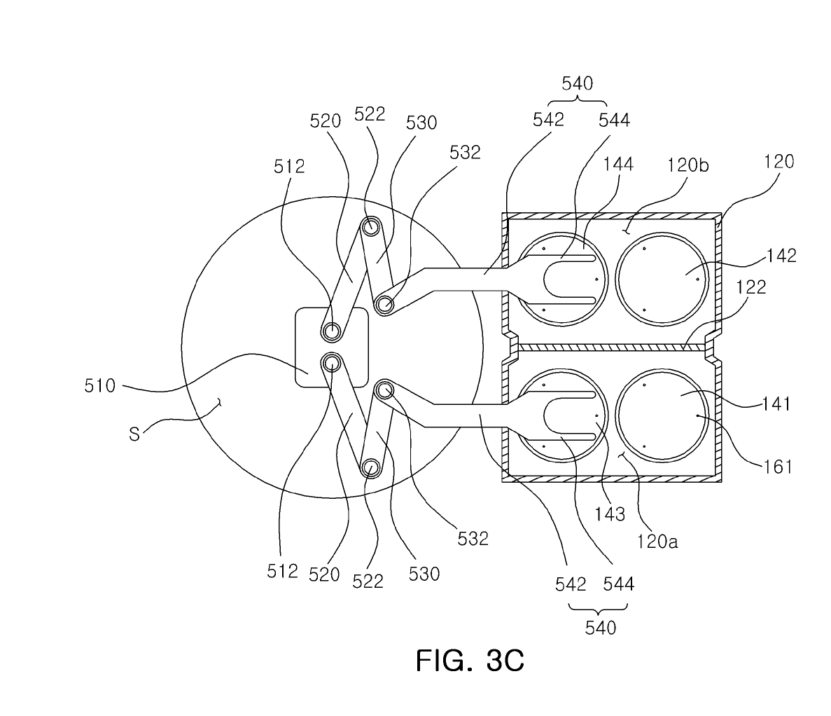

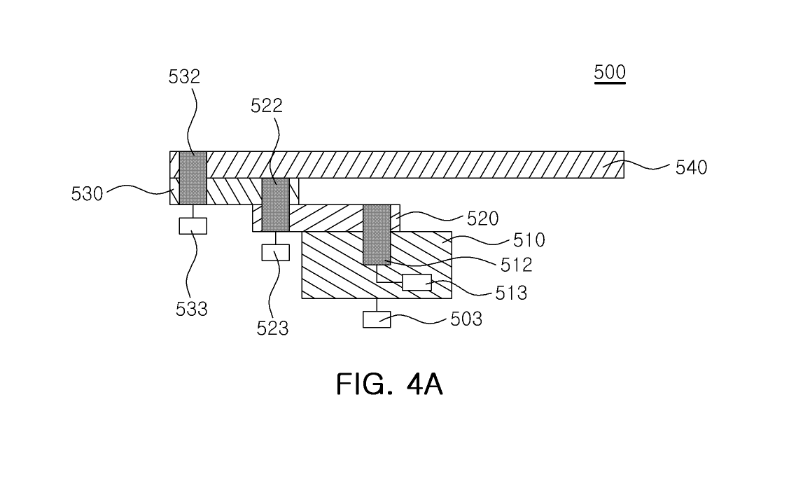

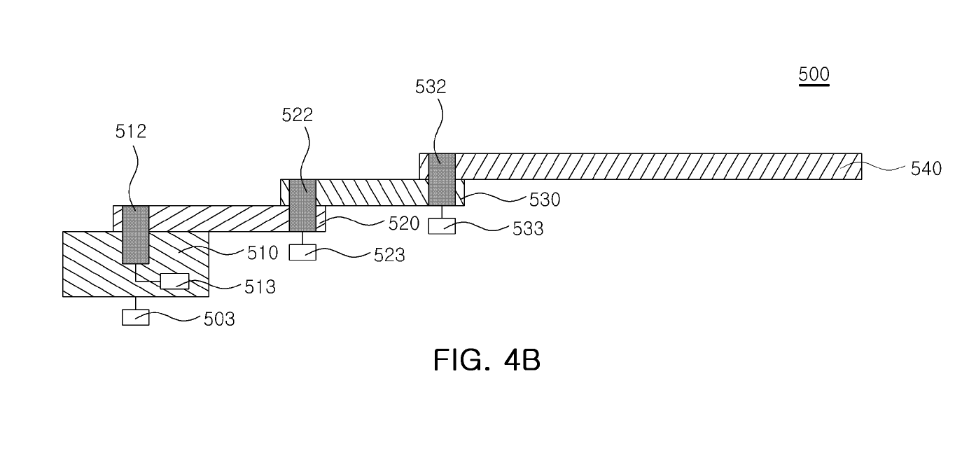

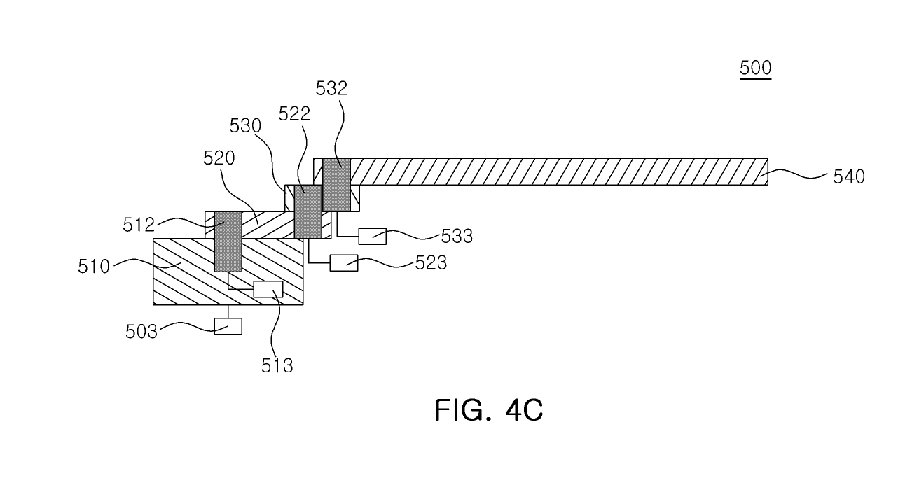

FIGS. 2A through 2C are views illustrating operational states of the substrate processing apparatus according to an exemplary embodiment of the present disclosure. FIGS. 3A through 3C are detailed views illustrating operational states of the substrate processing apparatus according to an exemplary embodiment of the present disclosure. FIGS. 4A through 4C are views illustrating operational states of a substrate transfer robot according to an exemplary embodiment of the present disclosure. As illustrated in FIGS. 2A through 4C, the substrate transfer robot 500 may include a base frame part 510, first rotating frame parts 520, second rotating frame parts 530, transfer frame parts 540, and a controlling part (not shown).

The base frame part 510 may be installed in a central portion of the internal space of the transfer chamber 102, and be connected to the first rotating frame parts 520 through first rotational axes 512. The base frame part 510 may be rotatably coupled to a lower surface of the transfer chamber 102 through a central axis (not shown). In this case, a central motor 503 may be connected to the central axis to provide the central axis with rotational driving force, thereby rotating the base frame part 510. The base frame part 510 may rotate, whereby holder portions 544 to be described later may be positioned in inlets of the transfer chamber 102 and the process chamber 120.

The first rotating frame parts 520 may be disposed above the base frame part 510 and have one ends rotatably connected to the base frame part 510 through the first rotational axes 512. In this case, a first motor 513 may be connected to the first rotational axis 512 to provide the first rotational axis 512 with rotational driving force, thereby rotating the first rotating frame part 520. The first rotating frame part 520 may rotate, whereby the holder portion 544 of the transfer frame part 540 connected to the first rotating frame part 520 may be positioned in an inlet of the loadlock chamber 106 or the substrate processing module 110.

One end of the first rotating frame part 520 may be positioned in the central portion of the internal space of the transfer chamber 102. The first rotating frame part 520 may have a linear form and a length less than a radius of the internal space of the transfer chamber 102. By doing so, the first rotating frame part 520 may rotate without being caught by inner side surfaces of the transfer chamber 102.

The second rotating frame parts 530 may be disposed above the first rotating frame parts 520 and have one ends rotatably connected to the other ends of the first rotating frame parts 520 through second rotational axes 522. In this case, a second motor 523 may be connected to the second rotational axis 522 to provide the second rotational axis 522 with rotational driving force, thereby rotating the second rotating frame part 530. That is, the second rotating frame part 530 may rotate in a state in which the holder portion 544 of the transfer frame 540 is positioned in the inlet of the loadlock chamber 106 or the substrate processing module 110, whereby the holder portion 544 may move inwardly or outwardly of the loadlock chamber 106 or the substrate processing module 110.

The transfer frame parts 540 may be disposed above the second rotating frame parts 530 and may respectively include arm portions 542 and the holder portions 544. One ends of the arm portions 542 may be rotatably connected to the other ends of the second rotating frame parts 530 through third rotational axes 532. In this case, a third motor 533 may be connected to the third rotational axis 532 to provide the third rotational axis 532 with rotational driving force, thereby rotating the transfer frame part 540. The holder portion 544 may be connected to the other end of the arm portion 542 and a substrate W may be disposed on the holder portion 544.

As illustrated in FIG. 2A, the transfer frame part 540 may have a linear form and a length L less than a diameter of an internal space S of the transfer chamber 102. When a position of the holder portion 544 of the transfer frame part 540 is moved to the inlet of the loadlock chamber 106 or the substrate processing module 110, the transfer frame part 540 may rotate without being caught by the inner side surfaces of the transfer chamber 102.

The controlling part may be connected to the central motor 503, the first motor 513, the second motor 523, and the third motor 533 and may control the central motor 503, the first motor 513, the second motor 523, and the third motor 533 in such a manner that the holder portion 544 is moved between a rotating position inside the transfer chamber 102 and a loading position inside the process chamber 120.

In this case, the loading position may be one of a first loading position in which the holder portions 544 may be disposed above first susceptors 141 and 142 and a second loading position in which the holder portions 544 may be disposed above second susceptors 143 and 144. That is, as in FIG. 2B, when the holder portions 544 are moved between the rotating position and the first loading position, the holder portions 544 may move by a distance L1. As in FIG. 2C, when the holder portions 544 are moved between the rotating position and the second loading position, the holder portions 544 may move by a distance L2.

In the loading position, the second rotating frame parts 530 and the holder portions 544 may be positioned on the same side based on the first rotating frame parts 520. In the rotating position, the second rotating frame parts 530 and the holder portions 544 may be positioned on opposite sides based on the first rotating frame parts 520.

In addition, when the holder portion 544 is moved between the rotating position and the loading position, the controlling part may rotate the first motor 513 and the third motor 533 in the same direction, while rotating the second motor 523 in a direction different from that of the first motor 513.

Hereinafter, with reference to FIGS. 3A through 3C, a process of transferring a plurality of substrates to the process chamber 120 by the substrate transfer robot 500 will be explained.

First, as illustrated in FIG. 3A, a preparation process of positioning the transfer frame parts 540 within the internal space S of the transfer chamber 102 by the rotation of the first rotating frame parts 520 and the second rotating frame parts 530 may be performed.

Then, as illustrated in FIG. 3B, a first transfer process of positioning the holder portions 544 of the transfer frame parts 540 above the first susceptors 141 and 142 by the rotation of the first rotating frame parts 520 and the second rotating frame parts 530 may be performed.

Then, as illustrated in FIG. 3C, a second transfer process of positioning the holder portions 544 of the transfer frame parts 540 above the second susceptors 143 and 144 by the rotation of the first rotating frame parts 520 and the second rotating frame parts 530 may be performed.

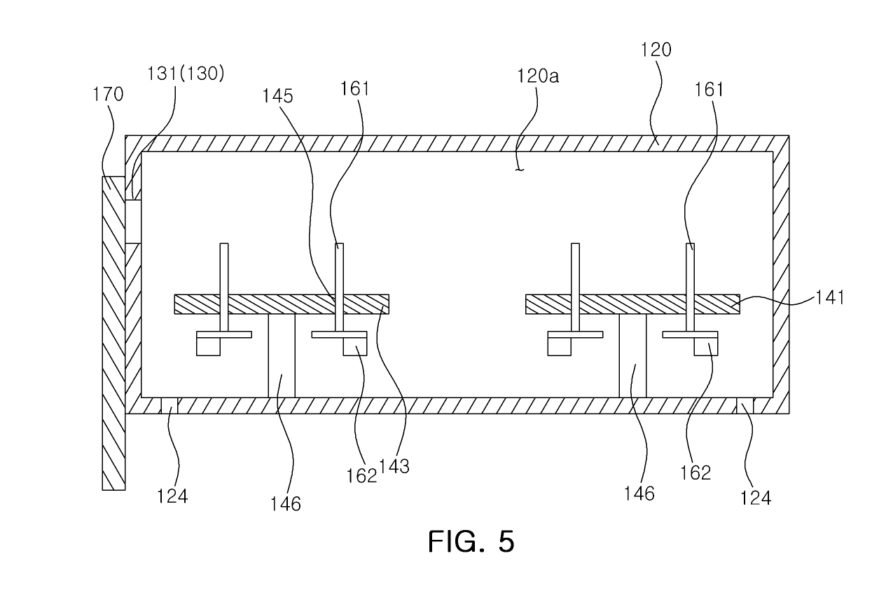

FIG. 5 is a cross-sectional view of a substrate processing module according to an exemplary embodiment of the present disclosure. Referring to FIG. 5, the substrate processing module 110 may include the process chamber 120, a plurality of the susceptors 141, 142, 143 and 144, a plurality of lift pins 161, and lift pin-driving modules 162.

The process chamber 120 may provide a process space and a process may be performed on the substrate W within the process space. A partition 122 may be installed within the process chamber 120, and the process space of the process chamber 120 may be divided into a first process space 120a and a second process space 120b by the partition 122.

The process chamber 120 may have passages 130 formed in one side thereof, and substrates W1 and W2 may be introduced inside the process chamber 120 through the passages 130. That is, one side of the process chamber 120 corresponding to the first process space 120a may be provided with a first passage 131, and one side of the process chamber 120 corresponding to the second process space 120b may be provided with a second passage (not shown). A gate valve 170 may be installed on the outside of the first and second passages 130, and the first and second passages 130 may be opened or closed by the gate valve 170. As described above, the substrate transfer robot 500, together with the substrates W1 and W2, may move inwardly of the process chamber 120 through the first and second passages 130. After disposing the substrates W1 and W2 on upper ends of the lift pins 161 to be described later or fork portions 155, the substrates W1 and W2 may move outwardly of the process chamber 12 through the first and second passages 130. In this case, the first and second passages 130 may be opened by the gate valve 170.

The process chamber 120 may have discharge ports 124 formed in edges of the bottom surface thereof, and the discharge ports 124 may be respectively disposed outwardly of the susceptors 141, 142, 143, and 144. A reaction product and unreacted gas maybe discharged outwardly of the process chamber 120 through the discharge ports 124.

The plurality of susceptors 141, 142, 143, and 144 may be installed within the process chamber 120, and a plurality of through holes 145 may be formed to penetrate through upper surfaces of the susceptors 141, 142, 143, and 144. The first susceptors 141 and 142 and the second susceptors 143 and 144 maybe sequentially disposed in parallel in a direction in which the substrate W is introduced. The second susceptors 143 and 144 may be disposed in positions corresponding to the first and second passages 130, and the first susceptors 141 and 142 may be disposed inwardly of the second susceptors 143 and 144. In this case, the substrates W1 and W2 may move inwardly of the process chamber 120 through the substrate transfer robot 500 and at the time of conducting the process, the substrates W1 and W2 may be disposed on the first susceptors 141 and 142 and the second susceptors 143 and 144. The first susceptors 141 and 142 and the second susceptors 143 and 144 may be respectively supported by support axes 146 and the support axes 146 may be fixed to the bottom surface of the process chamber 120.

The second susceptors 143 and 144 may be respectively positioned in front of the first and second passages 130 (in the direction in which the substrates W1 and W2 move inwardly of the process chamber 120 through the passages 130). Processes may be initiated in a state in which individual substrates W1 and W2 are respectively disposed on all of the susceptors 141, 142, 143, and 144. The processes maybe simultaneously performed on the respective substrates W1 and W2. Thus, processes for four sheets of substrates may be completed at one time, whereby productivity may be secured.

The lift pins 161 may be installed below the susceptors 141, 142, 143, and 144 and be movable through the through holes 145. That is, the upper ends of the lift pins 161 may penetrate through the through holes 145 of the susceptors 141, 142, 143, and 144 to protrude from the upper surfaces of the susceptors 141, 142, 143, and 144 and thus, may be positioned at a receiving height to be described later. The upper ends of the lift pins 161 may be disposed within the through holes 145 or below the susceptors 141, 142, 143, and 144 to thereby be positioned at a loading height. The lift pins 161 may respectively receive the substrates W1 and W2 at the receiving height from the substrate transfer robot 500, and the lift pins 161 may move at the loading height, whereby the received substrates W1 and W2 may be disposed on the susceptors 141, 142, 143 and 144. The lift pins 161 may rise or descend by the lift pin-driving modules 162.

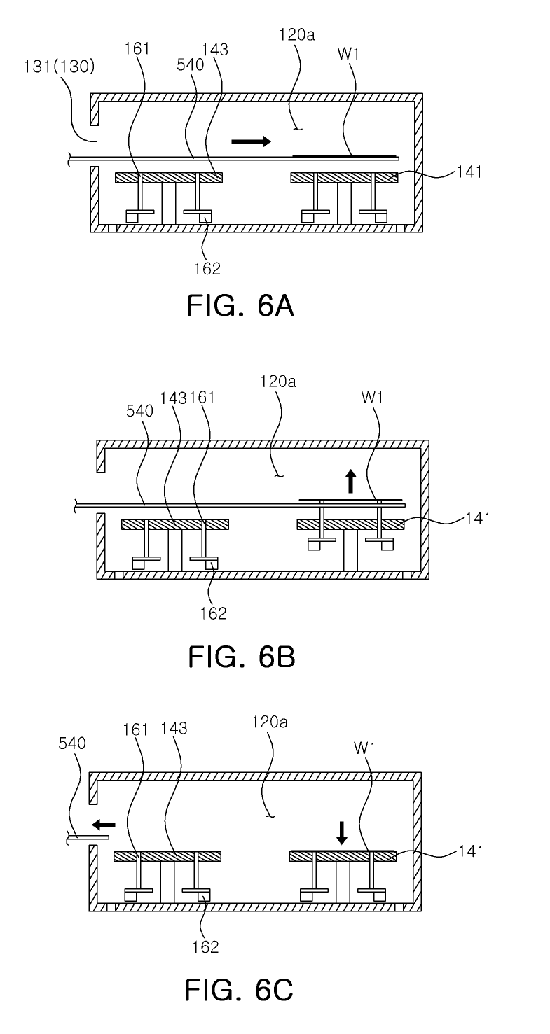

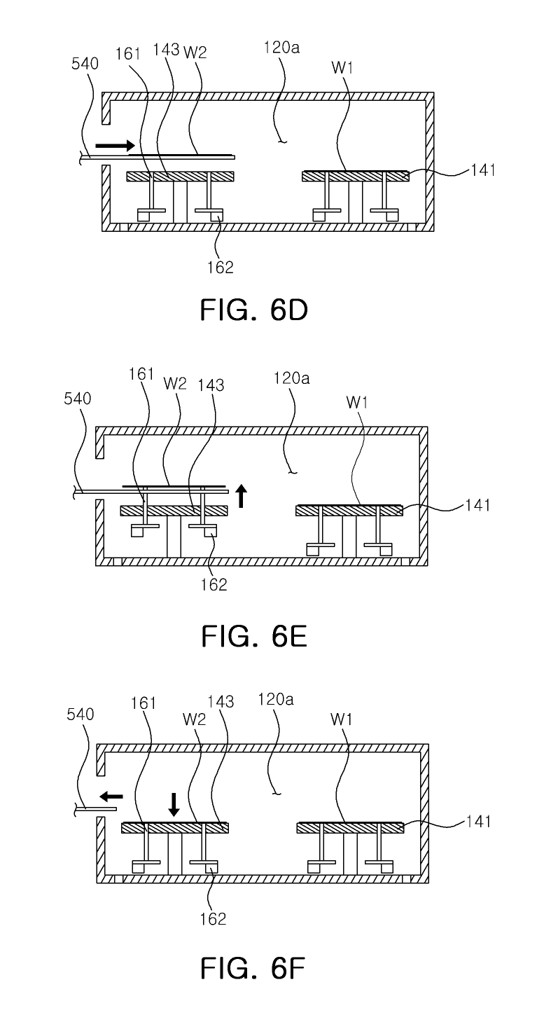

FIGS. 6A through 6F are views illustrating a process of transferring the substrate according to an exemplary embodiment of the present disclosure to the process chamber. Referring to FIGS. 6A through 6F, a process of seating the substrates W1 and W2 on the first susceptors 141 and 142 and the second susceptors 143 and 143 will be described.

First, the holder portions 544 on which the substrates W1 are disposed may be positioned on the first susceptors 141 and 142 by the substrate transfer robot 500.

Then, the upper ends of the lift pins 161 for the first susceptors 141 and 142 may be disposed in a position (“receiving height”) higher than that of the holder portions 544 by the lift-pin driving modules 162. In the case, the substrates W1 may be disposed on the upper ends of the lift pins 161.

Then, the holder portions 544 may be transferred to the outside of the process chamber 120 through the passages 30. In this case, the substrates W2 to be transferred to the process chamber 120 may be disposed on the holder portions 544. In addition, the upper ends of the lift pins 161 may be disposed in a position (“loading height”) lower than the upper surfaces of the first susceptors 141 and 142. That is, the substrates W1 may be disposed on the upper surfaces of the first susceptors 141 and 142.

Then, the holder portions 544 on which the substrates W2 are disposed may be positioned on the second susceptors 143 and 144 by the substrate transfer robot 500.

Then, the lift pins 161 for the second susceptors 143 and 144 may be disposed at the receiving height by the lift-pin driving modules 162. In the case, the substrates W2 may be disposed on the upper ends of the lift pins 161.

Then, the holder portions 544 may be transferred to the outside of the process chamber 120 through the passages 30. In addition, the lift pins 161 may be disposed at the loading height. That is, the substrates W2 maybe disposed on the upper surfaces of the second susceptors 143 and 144.

As described above, the order of disposing the substrates W1 on the first susceptors 141 and 142 and subsequently, disposing the substrates W2 on the second susceptors 143 and 144 is described, but it goes without saying that the substrates W1 may be disposed on the first susceptors 141 and 142 after the substrates W2 are disposed on the second susceptors 143 and 144.

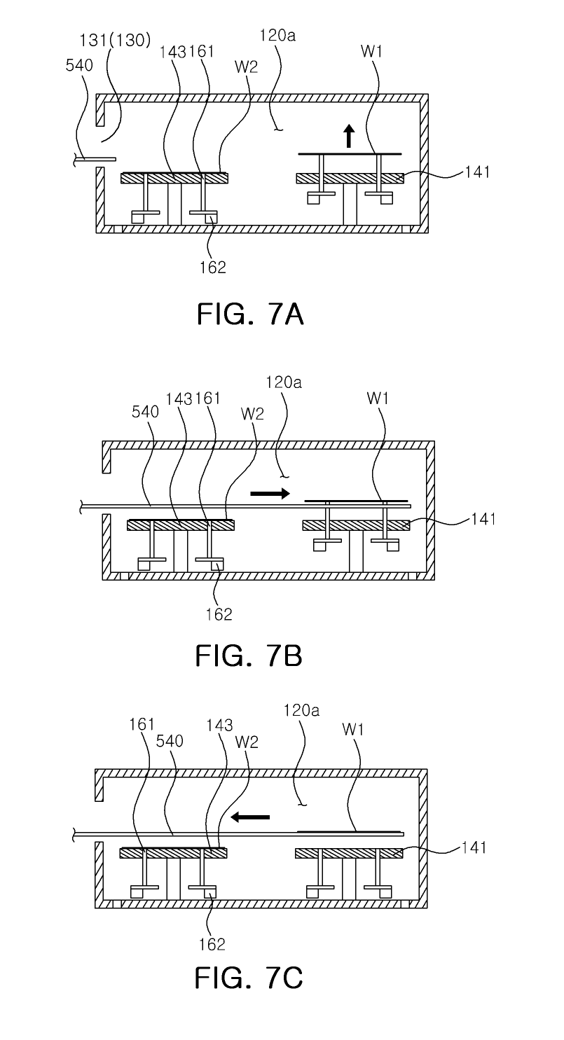

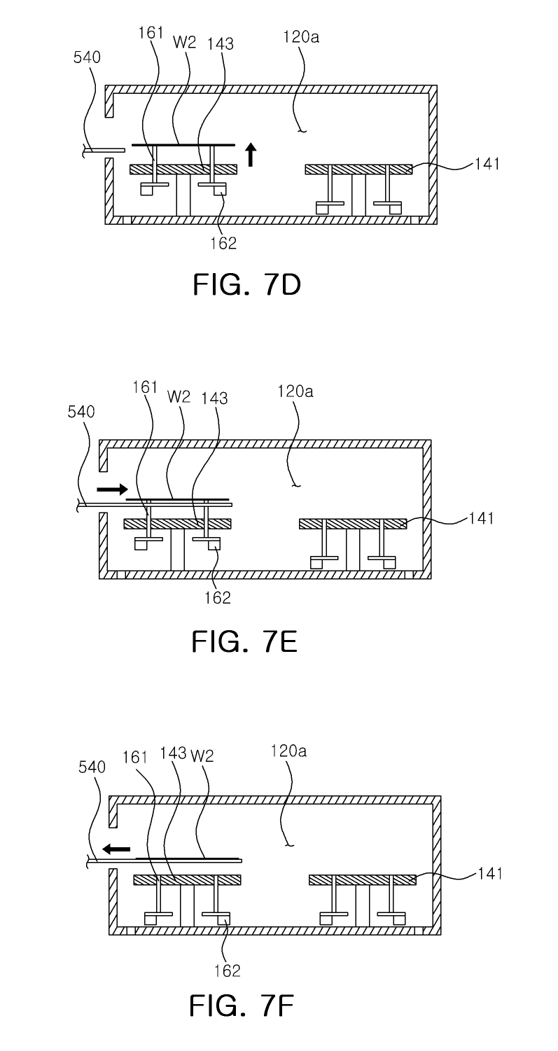

FIGS. 7A through 7F are views illustrating a process of drawing the substrate according to an exemplary embodiment of the present disclosure from the process chamber. Referring to FIGS. 7A through 7F, a process of separating the substrates W1 and W2 from the first susceptors 141 and 142 and the second susceptors 143 and 143 will be described.

First, the lift-pin driving modules 162 may allow the lift pins 161 for the first susceptors 141 and 142 to move to the receiving height.

Then, the holder portions 544 may move upwardly of the first susceptors 141 and 142 by the substrate transfer robot 500.

Then, the lift-pin driving modules 162 may allow the lift pins 161 for the first susceptors 141 and 142 to move to the loading height. The holder portions 544 may move to the outside of the process chamber 120 through the passages 30. In this case, the substrates W1 disposed on the holder portions 544 may be transferred to the loadlock chamber 106 by the substrate transfer robot 500.

Next, the lift-pin driving modules 162 may allow the lift pins 161 for the second susceptors 143 and 144 to move to the receiving height.

Then, the holder portions 544 may move upwardly of the second susceptors 143 and 144 by the substrate transfer robot 500.

Then, the lift-pin driving modules 162 may allow the lift pins 161 for the second susceptors 143 and 144 to move to the loading height. The holder portions 544 may be transferred to the outside of the process chamber 120 through the passages 30. In this case, the substrates W2 disposed on the holder portions 544 may be transferred to the loadlock chamber 106 by the substrate transfer robot 500.

As described above, the order of separating the substrates W1 from the first susceptors 141 and 142 and subsequently, separating the substrates W2 from the second susceptors 143 and 144 is described, but it goes without saying that the substrates W1 may be separated from the first susceptors 141 and 142 after the substrates W2 are separated from the second susceptors 143 and 144.

As described above, the plurality of substrates may access the process chamber while not increasing a size of the transfer chamber by rotation of the first rotating frame part, the second rotating frame part, and the transfer frame part.

As set forth above, according to exemplary embodiments of the present disclosure, the number of substrates inside the process chamber may be increased while not increasing the size of the transfer chamber. In addition, processes may be simultaneously conducted on the plurality of substrates.

While exemplary embodiments have been shown and described above, it will be apparent to those skilled in the art that modifications and variations could be made without departing from the spirit and scope of the present disclosure as defined by the appended claims.

What is claimed is:

1. A substrate processing apparatus comprising:
a loadlock chamber in which a substrate transferred from the outside is disposed, and an internal state thereof is changed to a vacuum state and an atmospheric pressure state;
a substrate processing module in which a process is performed on the substrate;
a transfer chamber in which the substrate is transferred, the transfer chamber being disposed between the loadlock chamber and the substrate processing module; and
a substrate transfer robot installed within the transfer chamber and transferring the substrate,
wherein the substrate transfer robot includes:
a base frame part rotatably installed on a lower portion of the transfer chamber;
a first rotating frame part having one end rotatably connected to the base frame part;
a second rotating frame part having one end rotatably connected to the other end of the first rotating frame part; and
a transfer frame part including an arm portion having one end rotatably connected to the other end of the second rotating frame part and a holder portion connected to the other end of the arm portion and allowing the substrate to be disposed on the holder portion.

2. The substrate processing apparatus of claim 1, wherein the transfer chamber has an internal space having a circular horizontal cross-section,
the first rotating frame part has a linear form and a length less than a radius of the internal space, and
the one end of the first rotating frame part is positioned in a central portion of the internal space.

3. The substrate processing apparatus of claim 1, wherein the transfer chamber has an internal space having a circular horizontal cross-section, and
the transfer frame part has a linear form and a length less than a diameter of the internal space.

4. The substrate processing apparatus of claim 1, wherein the substrate transfer robot includes:
a central axis coupled to the transfer chamber and the base frame part;
a first rotational axis coupled to the base frame part and the one end of the first rotating frame part;
a second rotational axis coupled to the other end of the first rotating frame part and the one end of the second rotating frame part;
a third rotational axis coupled to the other end of the second rotating frame part and the one end of the arm portion; and
a central motor, a first motor, a second motor, and a third motor connected to the central axis, the first rotational axis, the second rotational axis, and the third rotational axis, respectively, to provide the central axis, the first rotational axis, the second rotational axis, and the third rotational axis with rotational driving force.

5. The substrate processing apparatus of claim 4, wherein the substrate processing module includes:
a process chamber including a first process space and a second process space divided by a partition and having a first passage and a second passage formed in one side thereof, the first passage and the second passage allowing the substrate to access the first process space and the second process space;
a first susceptor installed within the process chamber, disposed in front of each of the first passage and the second passage, having a plurality of through holes formed to penetrate through upper and lower portions thereof, and allowing the substrate to be disposed on the first susceptor during the process;
a second susceptor installed within the process chamber, disposed between the first passage and the first susceptor and between the second passage and the first susceptor, having a plurality of through holes formed to penetrate through upper and lower portions thereof, and allowing the substrate to be disposed on the second susceptor during the process; and
a plurality of lift pins installed below the first susceptor and the second susceptor and movable through the through holes.

6. The substrate processing apparatus of claim 5, wherein the substrate processing module includes lift pin-driving modules allowing upper ends of the lift pins to be moved to a receiving height higher than the holder portion and a loading height lower than an upper surface of the susceptor.

7. The substrate processing apparatus of claim 5, wherein the substrate transfer robot includes a controlling part connected to the central motor, the first motor, the second motor, and the third motor, and controlling the central motor, the first motor, the second motor, and the third motor in such a manner that the holder portion is moved between a rotating position inside the transfer chamber and a loading position inside the substrate processing module.

8. The substrate processing apparatus of claim 7, wherein the loading position is one of a first loading position in which the holder portion is disposed above the first susceptor and a second loading position in which the holder portion is disposed above the second susceptor.

9. The substrate processing apparatus of claim 7, wherein in the loading position, the second rotating frame part and the holder portion are positioned on the same side based on the first rotating frame part.

10. The substrate processing apparatus of claim 7, wherein in the rotating position, the second rotating frame part and the holder portion are positioned on opposite sides based on the first rotating frame part.

11. The substrate processing apparatus of claim 7, wherein when the holder portion is moved between the rotating position and the loading position, the controlling part rotates the first motor and the third motor in the same direction while rotating the second motor in a direction different from that of the first motor.

12. A substrate transfer robot comprising:
a rotatable base frame part;
at least one rotating frame part rotatably connected to the base frame part in series;
a transfer frame part including an arm portion having one end rotatably connected to the rotating frame part and a holder portion connected to the other end of the arm portion and allowing a substrate to be disposed on the holder portion; and
a controlling part connected to the base frame part, the rotating frame part, and the transfer frame part and rotating the base frame part, the rotating frame part, and the transfer frame part to limit a moving distance of the holder portion.
